(19) United States
(12) Patent Application Publication
(10) Pub. No.: US 2024/0164185 A1
(43) Pub. Date: May 16, 2024

(54) ELECTROLUMINESCENT DISPLAY DEVICE

(71) Applicant: LG Display Co., Ltd., Seoul (KR)

(72) Inventor: HeeSuk PANG, Paju-si (KR)

(73) Assignee: LG Display Co., Ltd., Seoul (KR)

(21) Appl. No.: 18/224,880

(22) Filed: Jul. 21, 2023

(30) Foreign Application Priority Data
Nov. 15, 2022 (KR) 10-2022-0152891

(51) Int. Cl. H10K 59/80; H10K 59/131

(52) U.S. Cl. CPC H10K 59/873; H10K 59/131; H10K 59/8722

(57) ABSTRACT

Discussed is an electroluminescent display device including a display part including an active area and a non-active area. Further, the electroluminescent display device includes an encapsulation part disposed over the display part and one or more flexible films attached to one side of the display part. Further, the electroluminescent display device includes a low potential power line supplied with low potential power from the one or more flexible films. Furthermore, the electroluminescent display device includes a conductive element which is coated on a side surface of the encapsulation part adjacent the one or more flexible films and connected to the low potential power line.

### CROSS-REFERENCE TO RELATED APPLICATIONS

This application claims priority to Korean Patent Application No. 10-2022-0152891 filed on Nov. 15, 2022, in the Republic of Korea, the entire contents of which is hereby expressly incorporated by reference into the present application.

### BACKGROUND OF THE DISCLOSURE

### Field

The present disclosure relates to an electroluminescent display device, and more particularly, to an electroluminescent display device capable of improving electromagnetic interference (EMI).

### Discussion of the Related Art

The present era is being referred to as an information age because the field of display devices for visually displaying electrical information signals is rapidly developing. Thus, work in developing improvements such as making thinner, weight reduction, and low power consumption for the display devices have continued.

Representative examples of the display devices include a liquid crystal display (LCD) device, an electro-wetting display (EWD) device, an organic light emitting display (OLED) device, and the like.

An electroluminescent display device can refer to various display devices that includes the OLED device, and the electroluminescent display device is a self-emitting display device that does not require a separate light source unlike the LCD device that requires a separate backlight unit. Thus, the electroluminescent display device can be manufactured in a lightweight and thin form. Further, the electroluminescent display device is not only advantageous in terms of power consumption by low voltage driving, but also has excellent color expression ability, response speed, viewing angle and contrast ratio (CR). Therefore, the electroluminescent display device is expected to be utilized in various fields in the coming years.

### SUMMARY OF THE DISCLOSURE

An aspect of the present disclosure is to provide an electroluminescent display device with increased rigidity of a display panel and improved heat dissipation.

Another aspect of the present disclosure is to provide an electroluminescent display device capable of improving electromagnetic interference (EMI).

Accordingly, embodiments of the present disclosure are directed to an apparatus that substantially obviates one or more of the problems due to limitations and disadvantages of the related art.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

According to an aspect of the present disclosure, the electroluminescent display device includes a display part including an active area and a non-active area. Further, the electroluminescent display device includes an encapsulation part disposed over the display part and a flexible film attached to one side of the display part. Further, the electroluminescent display device includes a low potential power line supplied with low potential power from the flexible film. Furthermore, the electroluminescent display device includes a conductive paste which is coated on a side surface of the encapsulation part between the flexible films and of which one side is connected to the low potential power line.

According to the present disclosure, an encapsulation structure has a multilayer structure including a relatively thick reinforcing substrate. Thus, it is possible to achieve sufficient rigidity and heat dissipation.

According to the present disclosure, a conductive paste is applied to a side surface of an encapsulation part and connected to a contact portion of a low potential power line (VSS) between source pads. Thus, it is possible to improve EMI.

Other systems, methods, features and advantages will be, or will become, apparent to one with skill in the art upon examination of the following figures and detailed description. It is intended that all such additional systems, methods, features and advantages included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a block diagram showing an electroluminescent display device according to a first exemplary embodiment of the present disclosure;

FIG. 2 is a circuit diagram of a sub-pixel of the electroluminescent display device of FIG. 1;

FIG. 3 through FIG. 5 are views schematically illustrating the planar structure of the electroluminescent display device of FIG. 1;

FIG. 6 is a cross-sectional view as taken along a line I-I′ of FIG. 3;

FIG. 7 is a cross-sectional view showing a sub-pixel of the electroluminescent display device of FIG. 6;

FIG. 8 is a cross-sectional view schematically illustrating an electroluminescent display device according to a second exemplary embodiment of the present disclosure;

FIG. 9 is a cross-sectional view schematically illustrating an electroluminescent display device according to a third exemplary embodiment of the present disclosure;

FIG. 10 is a cross-sectional view schematically illustrating an electroluminescent display device according to a fourth exemplary embodiment of the present disclosure; and

FIG. 11 and FIG. 12 are plan views schematically illustrating an electroluminescent display device according to a fifth exemplary embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

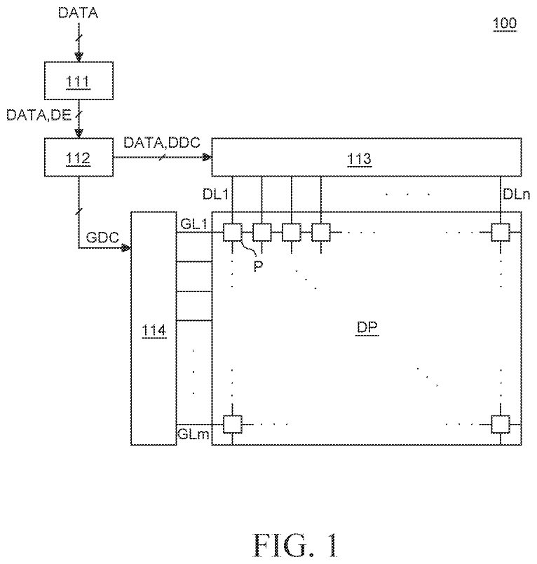

FIG. 1 is a block diagram showing an electroluminescent display device according to a first example embodiment of the present disclosure.

Referring to FIG. 1, an electroluminescent display device 100 according to a first example embodiment of the present disclosure can include an image processor 111, a timing controller 112, and a data driver 113. Further, the electroluminescent display device 100 includes a gate driver 114 and a display part DP.

The image processor 111 can output a data signal DATA and a data enable signal DE supplied from the outside. The image processor 111 can output one or more of a vertical sync signal, a horizontal sync signal, and a clock signal in addition to the data enable signal DE. Vertical and horizontal sync signals may be used to define the ends of each line and frame.

The timing controller 112 receives the data signal DATA and a driving signal including the data enable signal DE or the vertical sync signal, the horizontal sync signal, and the clock signal from the image processor 111. The timing controller 112 can output a gate timing control signal GDC for controlling operation timing of the gate driver 114 and a data timing control signal DDC for controlling operation timing of the data driver 113 based on the driving signal.

Further, the data driver 113 can sample and latch the data signal DATA supplied from the timing controller 112 in response to the data timing control signal DDC supplied from the timing controller 112. Then, the data driver 113 can convert the sampled and latched data signal DATA into a gamma reference voltage and output the gamma reference voltage. The data driver 113 can output the data signal DATA through data lines DL1 to DLn.

The gate driver 114 can output a gate signal while shifting the level of a gate voltage in response to the gate timing control signal GDC supplied from the timing controller 112. The gate driver 114 can output the gate signal through gate lines GL1 to GLm.

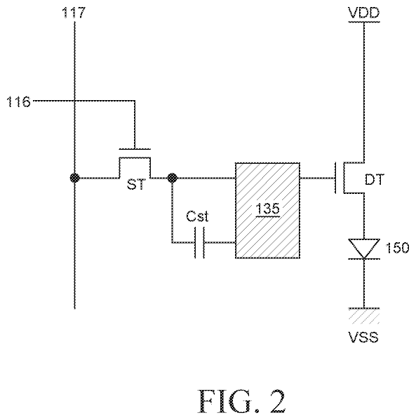

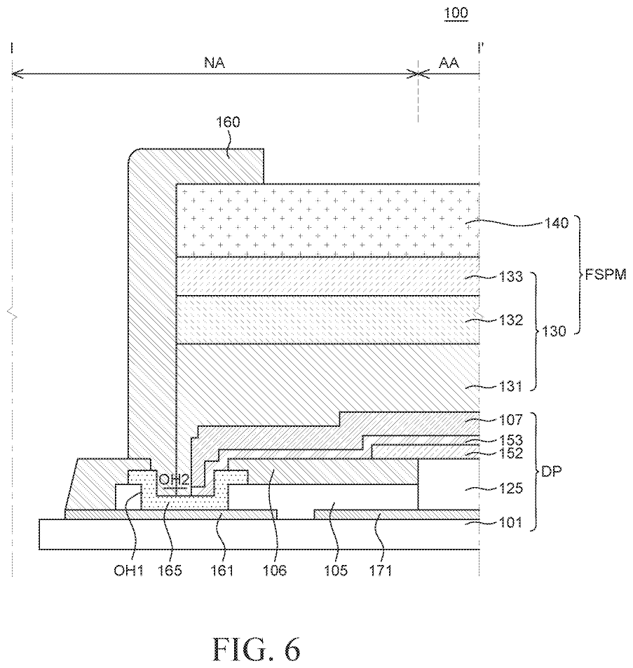

The display part DP can display an image while sub-pixels P emit light in response to the data signal DATA and the gate signal respectively received from the data driver 113 and the gate driver 114. A detailed structure of each sub-pixel P will be described with reference to FIG. 2 and FIG. 6.

FIG. 2 is a circuit diagram of a sub-pixel of the electroluminescent display device of FIG. 1.

Referring to FIG. 2, the sub-pixel of the electroluminescent display device according to the first example embodiment of the present disclosure can include a switching transistor ST and a driving transistor DT. Further, the sub-pixel can include a compensation circuit 135 and a light emitting diode 150.

The light emitting diode 150 can operate to emit light in response to a driving current formed by the driving transistor DT.

The switching transistor ST can perform a switching operation so that a data signal supplied through a data line 117 is stored in a capacitor CST as a data voltage in response to a gate signal supplied through a gate line 116.

The driving transistor DT can operate so that a constant driving current flows between a high potential power line VDD and a low potential power line VSS in response to the data voltage stored in the capacitor CST.

The compensation circuit 135 is a circuit for compensating for a threshold voltage of the driving transistor DT. The compensation circuit 135 can include one or more thin film transistors and a capacitor. A configuration of the compensation circuit 135 can be variously modified depending on a compensation method.

The sub-pixel shown in FIG. 2 has a 2T (transistor)-1c (capacitor) structure including the switching transistor ST, the driving transistor DT, the capacitor CST, and the light emitting diode 150. However, when the compensation circuit 135 is added to the sub-pixel, the sub-pixel can have various structures of 3T1C, 4T2C, 5T2C, 6T1C, 6T2C, 7T1C, 7T2C, and the like.

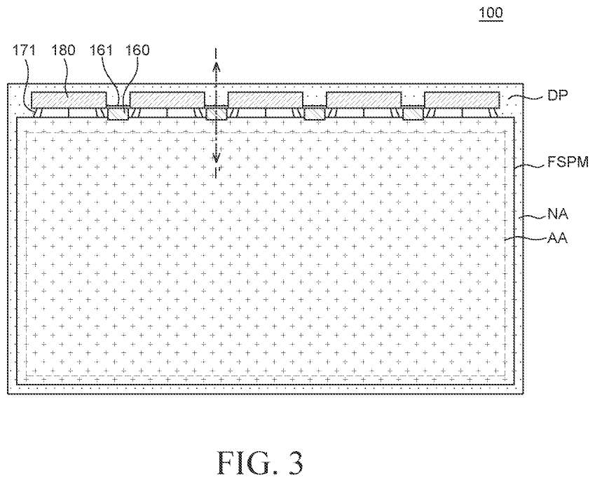

FIG. 3 through FIG. 5 are views schematically illustrating the planar structure of the electroluminescent display device of FIG. 1.

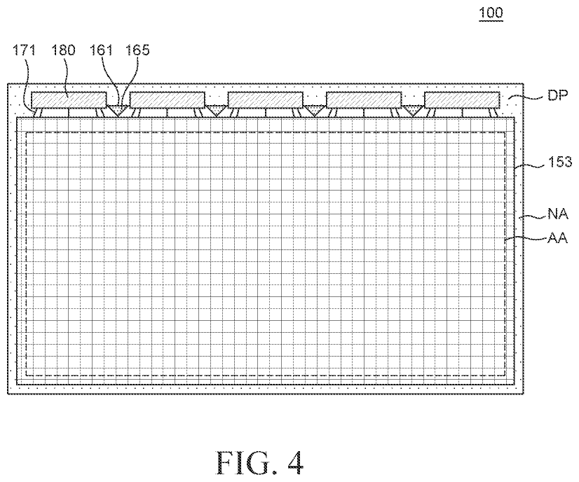

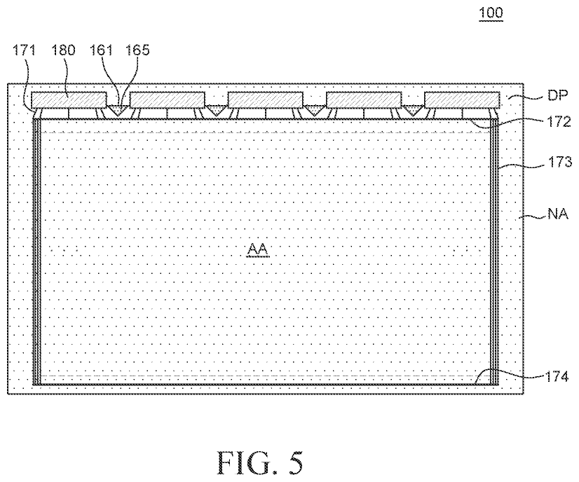

FIG. 3 illustrates the planar structure of the electroluminescent display device 100 in which an encapsulation part FSPM is disposed on the display part DP. FIG. 4 and FIG. 5 illustrate the planar structure of the electroluminescent display device 100 in which the encapsulation part FSPM is removed. Particularly, FIG. 4 illustrates the planar structure of the electroluminescent display device 100 in which a cathode 153 is disposed.

Referring to FIG. 3 through FIG. 5, the electroluminescent display device 100 according to the first example embodiment of the present disclosure can include the display part DP, the encapsulation part FSPM, and one or more flexible film 180.

The display part DP is a panel for displaying an image to a user.

For example, the display part DP can include a display element to display an image, a driving element to drive the display element, and a line to transmit various signals to the display element and the driving element. The display element can be defined in different ways depending on the type of the display part DP. For example, if the display part DP is an organic light emitting display panel, the display element can be an organic light emitting diode which includes an anode, an organic layer, and a cathode. For example, if the display part DP is a liquid crystal display panel, the display element can be a liquid crystal display element.

Hereinafter, even though the display part DP will be described as an organic light emitting display panel, the display part DP of the present disclosure is not limited to the organic light emitting display panel.

The display part DP can include an active area AA and a non-active area NA.

The active area AA is an area where an image is displayed in the display part DP.

A plurality of sub-pixels forming a plurality of pixels and a circuit for driving the plurality of sub-pixels can be disposed in the active area AA. The active area AA comprises at least the plurality of sub-pixels, and a display element can be disposed on each of the plurality of sub-pixels. The plurality of sub-pixels can form a pixel. For example, an organic light emitting diode composed of, or including an anode, an organic layer, and a cathode can be disposed on each of the plurality of sub-pixels. However, embodiments of the present disclosure are not limited thereto. Further, the circuit for driving the plurality of sub-pixels can include a driving element and a line. For example, the circuit can be composed of, or include a thin film transistor, a storage capacitor, a gate line, a data line, etc., but is not limited thereto.

The non-active area NA is an area where an image is not displayed.

Although FIG. 3 through FIG. 5 illustrate that the non-active area NA encloses the active area AA having a rectangular shape, the shape and arrangement of the active area AA and the non-active area NA are not limited to the example illustrated in FIG. 3 through FIG. 5.

For example, the active area AA and the non-active area NA can have shapes suitable for a design of an electronic device equipped with the electroluminescent display device 100 according to the example embodiments of the present disclosure. For example, the active area AA can have a pentagonal shape, a hexagonal shape, a circular shape, an oval shape, and the like.

In the non-active area NA, various lines and circuits for driving the organic light emitting diodes in the active area AA can be disposed. For example, a link line for transmitting a signal to the plurality of sub-pixels and the circuit in the active area AA, or a driver IC such as a gate driver IC or a data driver IC can be disposed in the non-active area NA. However, embodiments of the present disclosure are not limited thereto.

Further, the electroluminescent display device 100 can include various additional components for generating various signals or driving the pixels in the active area AA. For example, the additional components for driving the pixels can include an inverter circuit, a multiplexer, an electrostatic discharge (ESD) circuit, and the like. The electroluminescent display device 100 can also include components associated with functions other than the function to drive the pixels. For example, the electroluminescent display device 100 can include additional components for providing a touch sensing function, a user authentication function (e.g., fingerprint scanning), a multi-level pressure sensing function, a tactile feedback function, etc. The above-described additional components can be located in the non-active area NA and/or on an external circuit connected to a connection interface.

The flexible film 180 can be a film in which various components are disposed on a base film having a malleability. Specifically, the flexible film 180 serves to supply a signal to the plurality of sub-pixels and the circuits of the active area AA, and can be electrically connected to the display part DP. The flexible film 180 can be disposed at one end of the display part DP to supply a power voltage or a data voltage to the plurality of sub-pixels and the circuits of the active area AA. Although five flexible films 180 are illustrated in FIG. 3 and FIG. 4 as an example, the number of flexible films 180 can vary depending on the design and is not limited to the illustrated example.

Meanwhile, a driving IC, such as a gate driver IC or a data driver IC, can be disposed on the flexible film 180. The driving IC can be a component to process data for displaying an image and a driving signal for processing the data. The driving IC can be disposed in a chip on glass (COG), chip on film (COF), or tape carrier package (TCP) manner depending on a mounting method.

Further, for example, a printed circuit board can be disposed at one end of the flexible film 180 and connected to the flexible film 180. For example, the printed circuit board can be a component to supply signals to the driving IC. Further, the printed circuit board can supply various signals, such as a driving signal or a data signal, to the driving IC. For example, a data driver to generate data signals can be mounted on the printed circuit board, and the generated data signals can be supplied to the sub-pixels and the circuits on the display part DP through the flexible film 180.

Meanwhile, the encapsulation part FSPM can be disposed on the display part DP.

The encapsulation part FSPM can be composed of, or include a sealing member and a reinforcing substrate.

According to the present disclosure, an encapsulation structure has a multilayer structure including a relatively thick reinforcing substrate. Thus, it is possible to achieve sufficient rigidity and heat dissipation. However, if a plastic polymer such as polyethylene terephthalate (PET) is used for the reinforcing substrate, it is difficult to suppress electromagnetic interference (EMI). For example, the display part DP and the mechanism components need to be electrically connected to avoid EMI in the electroluminescent display device 100. Herein, the encapsulation part FSPM of the present disclosure employs the reinforcing substrate made of a plastic polymer with an insulating adhesive layer interposed therebetween. Therefore, electrical connection (grounding) to the display part DP using a conductive tape on the encapsulation part FSPM as in a conventional method cannot be made. Further, according to the present disclosure, if a barrier layer made of, or including a metal material such as aluminum (Al) foil does not form a common ground with the cathode 153, a large capacitor equivalent in size to the display part DP can be formed. Thus, when a voltage is applied to the cathode 153, a short can occur in a circuit due to accumulation of charges.

According to the present disclosure, a conductive paste 160 can be applied to a side surface of the encapsulation part FSPM so as to be in contact with a side surface of the metallic barrier layer of the encapsulation part FSPM. Further, a low potential power line contact portion 165 connected to a low potential power line 161 can be exposed between the flexible films 180 or source pads so as to be electrically connected to the conductive paste 160. Thus, it is possible to improve EMI. The exposed side surface of the barrier layer is connected to the low potential power line 161 by using the conductive paste 160. Here, the low potential power line 161 can share a low potential power supply with the data driver IC. In embodiments of the present disclosure, a plurality of conductive pastes 160 can be provided between adjacent pair of a plurality of flexible films 180.

In embodiments of the present disclosure, a role or a function of the conductive paste 160 can be performed by any conductive material, including a metal strip, a conductive wire, an optically conductive adhesive, resins having conductive channels, foils or others that can conduct current. In various embodiments of the present disclosure, conductive paste 160 can be referred to as a conductive channel or a conductive element.

For example, the flexible film 180 can be attached to a tip end on one side of the display part DP so as to cover the source pad and the driving IC. Further, a power voltage and a data voltage can be supplied to the plurality of sub-pixels and the circuits in the active area AA through a link line 171.

For example, if the link line 171 is a high potential power line, it can be connected to a first short bar 172 disposed to be parallel to a width direction of the display part DP. Then, the link line 171 can be connected to a second short bar 174 through a plurality of high potential power lines 173 disposed in the active area AA. The plurality of high potential power lines 173 can be disposed to be parallel to a height direction of the display part DP.

For example, the link line 171 can be formed as a two-layer structure on a light shielding layer and a gate layer. Further, the first short bar 172 and the second short bar 174 can be formed on the gate layer, and the plurality of high potential power lines 173 can be formed on the light shielding layer. However, embodiments of the present disclosure are not limited thereto.

The first short bar 172 can be located at an upper end of the active area AA, and the second short bar 174 can be located at a lower end of the active area AA. However, embodiments of the present disclosure are not limited thereto.

The low potential power line 161 of the present disclosure can be disposed outside the or next to the link line 171 and between the or next to the flexible films 180. The low potential power line 161 can be formed as, or include a two-layer structure on the light shielding layer and the gate layer.

The low potential power line contact portion 165 is disposed on the low potential power line 161, and the low potential power line contact portion 165 can be in contact with (or connected to) the low potential power line 161.

The low potential power line contact portion 165 can be formed on an anode layer.

FIGS. 5 (and FIG. 4) illustrates an example where the low potential power line contact portion 165 has an inverse triangular shape between each of the flexible films 180, but embodiments of the present disclosure are not limited thereto. The low potential power line contact portion 165 can have a bar shape parallel to the width direction of the first short bar 172 between each of the flexible films 180. Alternatively, if high potential power lines are respectively disposed outside the outermost flexible films 180 on the left and right, the low potential power line contact portion 165 can be disposed to not overlap the high potential power lines. This is because if the low potential power line contact portion 165 overlaps the high potential power lines, a short-circuit can occur. For example, the low potential power line contact portion 165 can have a ring shape which is not disposed in a left upper end and a right upper end of the display part DP where high potential power lines can be respectively disposed. The low potential power line contact portion 165 having a ring shape can be in contact with an edge of the encapsulation part FSPM.

A part of an upper surface of the low potential power line contact portion 165 can be exposed as a planarization layer and/or a bank is removed. The cathode 153 and the conductive paste 160 can be disposed on the exposed part of the upper surface of the low potential power line contact portion 165 so as to be in contact with (or connected to) the low potential power line contact portion 165.

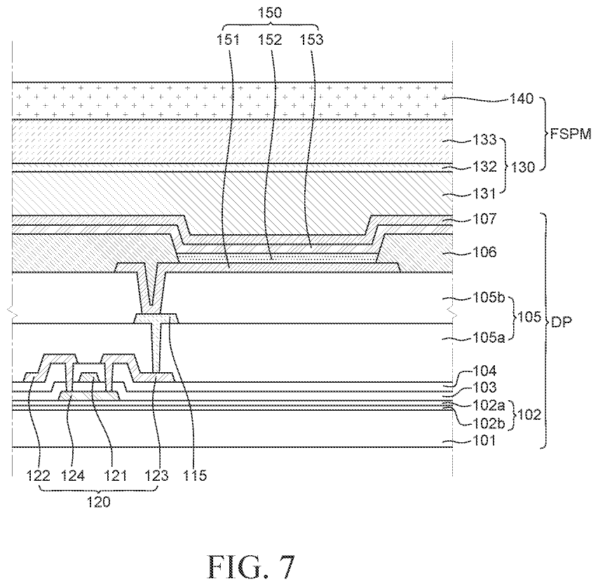

Hereinafter, a cross-sectional structure of the electroluminescent display device 100 of the present disclosure including a ground structure will be described in detail with reference to FIG. 6 and FIG. 7.

FIG. 6 is a cross-sectional view as taken along a line I-I′ of FIG. 3.

FIG. 7 is a cross-sectional view showing a sub-pixel of the electroluminescent display device of FIG. 6.

Some components of the display part DP is not illustrated in FIG. 6 for the convenience of description, and a pixel unit 125 in the active area AA is schematically illustrated.

FIG. 7 is a cross-sectional view showing a sub-pixel of the display part DP according to the first example embodiment of the present disclosure.

Referring to FIG. 6 and FIG. 7, a driving element 120 can be disposed on a substrate 101.

Further, a planarization layer 105 can be disposed on the driving element 120.

An organic light emitting diode 150 electrically connected to the driving element 120 is disposed on the planarization layer 105, and a capping layer 107 can be disposed on the organic light emitting diode 150.

A sealing member 130 and a reinforcing substrate 140 can be sequentially disposed on the capping layer 107. However, the reinforcing substrate 140 or the sealing member 130 can also be omitted, or if present, can be flexible or bendable, and embodiments of the present disclosure are not limited thereto, and a rigid or a semirigid reinforcing substrate 140 can be used.

The electroluminescent display device 100 according to the first example embodiment of the present disclosure is not limited to this laminated structure.

Specifically, the substrate 101 can be a glass or plastic substrate. If the substrate 101 is a plastic substrate, a polyimide-based or polycarbonate-based material can be used to have flexibility. In particular, polyimide can be applied to high temperature processes and is widely used for the plastic substrate because it is a material that can be coated.

A buffer layer 102 can be disposed on the substrate 101.

The buffer layer 102 serves to protect various electrodes/lines from impurities such as alkali ions or the like flowing out from the substrate 101 or lower layers. The buffer layer 102 can have a multilayer structure including a first buffer layer 102a and a second buffer layer 102b, but is not limited thereto. The buffer layer 102 can be formed of, or include silicon oxide (SiOx), silicon nitride (SiNx), or a multilayer thereof, and embodiments of the present disclosure are not limited thereto as organic materials, other inorganic materials, other ceramics, or oxides can be used for the buffer layer.

For example, the buffer layer 102 can delay diffusion of moisture and oxygen permeating into the substrate 101. The buffer layer 102 can include a multi buffer and/or an active buffer. The active buffer protects an active layer 124, which is made of, or includes a semiconductor, of the driving element 120, and can serve to block various kinds of impurities introduced from the substrate 101. The active buffer can be made of, or include amorphous silicon (a-Si) or the like.

Herein, for example, the driving element 120 can be composed of, or include the active layer 124, a gate electrode 121, a source electrode 122, and a drain electrode 123. The driving element 120 can be electrically connected to the organic light emitting diode 150 through a connection electrode 115 and thus can transmit a current or a signal to the organic light emitting diode 150.

The active layer 124 can be disposed on the buffer layer 102. The active layer 124 can be made of, or include polycrystalline silicon (p-Si). In this example, a predetermined region can be doped with impurities. The active layer 124 can also be made of, or include amorphous silicon (a-Si), or can be made of, or include various organic semiconductor materials, such as pentacene. Alternatively, the active layer 124 can be made of, or include an oxide semiconductor.

A gate insulating layer 103 can be disposed on the active layer 124.

The gate insulating layer 103 can be made of, or include an inorganic insulating material, such as silicon oxide (SiOx) or silicon nitride (SiNx), or can be made of, or include an organic insulating material, and embodiments of the present disclosure are not limited thereto.

The gate electrode 121 can be disposed on the gate insulating layer 103.

The gate electrode 121 can be made of, or include various conductive materials, such as nickel (Ni), chromium (Cr), magnesium (Mg), aluminum (Al), molybdenum (Mo), tungsten (W), gold (Au), or an alloy thereof, and embodiments of the present disclosure are not limited thereto.

The link line 171 can be disposed on the same layer as the gate electrode 121 in the non-active area NA. The link line 171 can extend to the active area AA.

The low potential power line 161 can be disposed on the same layer as the gate electrode 121 in the non-active area NA, but is not limited thereto. The low potential power line 161 can be disposed on the same layer as the source electrode 122 and the drain electrode 123. Alternatively, the low potential power line 161 can be formed as, or include a two-layer structure on the same layer as the gate electrode 121, the source electrode 122, and the drain electrode 123. The low potential power line 161 can extend to the outside of the encapsulation part FSPM. In other words, the low potential power line 161 may extend beyond an edge of the encapsulation part FSPM.

An interlayer insulating layer 104 can be disposed on the gate electrode 121.

The interlayer insulating layer 104 can be made of, or include an insulating material such as silicon oxide (SiOx) or silicon nitride (SiNx), or can be made of, or include an organic insulating material, and embodiments of the present disclosure are not limited thereto.

A contact hole can be formed by selectively removing the gate insulating layer 103 and the interlayer insulating layer 104 to expose a source region and a drain region of the active layer 124. For example, the source electrode 122 and the drain electrode 123 can be made of, or include an electrode material in a monolayer structure or a multilayer structure on the interlayer insulating layer 104. Further, the source electrode 122 and the drain electrode 123 can be connected to the source region and the drain region, respectively.

If necessary or desired, a passivation layer made of, or including an inorganic insulating material can also be formed to cover the source electrode 122 and the drain electrode 123, and embodiments of the present disclosure are not limited thereto.

The planarization layer 105 can be disposed on the driving element 120 configured as described above.

The planarization layer 105 can have a multilayer structure including at least two layers. For example, the planarization layer 105 can include a first planarization layer 105a and a second planarization layer 105b. The first planarization layer 105a is disposed to cover the driving element 120 and can be disposed to expose a part of the source electrode 122 and a part of the drain electrode 123 of the driving element 120.

For example, the planarization layer 105 can extend to the non-active area NA so as to cover a part of the link line 171 and a part of the low potential power line 161. For example, the planarization layer 105 can extend to the outside of the encapsulation part FSPM.

The planarization layer 105 can cover a part of the low potential power line contact portion 165.

A first open hole OH1 can be formed by removing a part of the planarization layer 105 to expose a part of an upper surface of the low potential power line contact portion 165.

The planarization layer 105 can have a thickness of about 2 μm, but is not limited thereto.

The planarization layer 105 can be an overcoat layer, but is not limited thereto.

Meanwhile, the connection electrode 115 can be disposed on the first planarization layer 105a to electrically connect the driving element 120 and the organic light emitting diode 150. In FIG. 7, various metal layers serving as lines/electrodes such as a data line or a signal line can be disposed on the first planarization layer 105a.

Further, the second planarization layer 105b can be disposed on the first planarization layer 105a and the connection electrode 115.

For example, the planarization layer 105 is composed of, or includes two layers in the display part DP according to the first example embodiment of the present disclosure. This is because the number of various signal lines increases as the resolution of the display part DP increases. Accordingly, it is difficult to dispose all the lines in a single layer so as to be spaced apart by a minimum distance from each other. Thus, an additional layer is formed. The lines can be disposed with space to spare due to the additional layer, i.e., the second planarization layer 105b. In other words, the lines may be disposed more compactly due to the additional layer. Therefore, it can be easier to design the layout of lines/electrodes. Further, if a dielectric material is used for the planarization layer 105 having a multilayer structure, the planarization layer 105 can be used to form capacitance between metal layers.

The second planarization layer 105b can be formed to expose a part of the connection electrode 115. The drain electrode 123 of the driving element 120 and an anode 151 of the organic light emitting diode 150 can be electrically connected to each other by the connection electrode 115.

The organic light emitting diode 150 can have a structure in which the anode 151, a plurality of organic layers 152, and a cathode 153 are sequentially disposed.

For example, the organic light emitting diode 150 can be composed of, or includes the anode 151 formed on the planarization layer 105, the organic layer 152 formed on the anode 151, and the cathode 153 formed on the organic layer 152.

The electroluminescent display device 100 can be of a top emission type or a bottom emission type depending on the direction of light emission. For the top emission type, light emitted from the organic layer 152 can be reflected from the anode 151 toward an upward direction, i.e., toward the cathode 153 thereabove. To this end, a reflective layer made of, or including an opaque conductive material having high reflectance such as silver (Ag), aluminum (Al), gold (Au), molybdenum (Mo), tungsten (W), chromium (Cr) or an alloy thereof can be further disposed under the anode 151, and embodiments of the present disclosure are not limited thereto. For the bottom emission type, the anode 151 can be made of, or include a transparent conductive material such as indium tin oxide (ITO), indium zinc oxide (IZO), indium gallium zinc oxide (IGZO) or the like, and embodiments of the present disclosure are not limited thereto. Hereinafter, the electroluminescent display device 100 of the present disclosure will be described as a bottom emission type electroluminescent display device.

For example, the low potential power line contact portion 165 can also be disposed on the same layer as the anode 151 in the non-active area NA. The low potential power line contact portion 165 can be connected to the low potential power line 161 through the first open hole OH1. As described above, the low potential power line contact portion 165 can have an inverse triangular shape between each of the flexible films 180. Alternatively, the low potential power line contact portion 165 can have a bar shape parallel to the width direction of the first short bar 172 between each of the flexible films 180. If high potential power lines are respectively disposed outside the outermost flexible films on the left and right, the low potential power line contact portion 165 can be disposed not to overlap the high potential power lines. For example, the low potential power line contact portion 165 can have a ring shape which is not disposed in the left upper end and the right upper end of the display part DP where high potential power lines are respectively disposed.

A bank 106 can be formed on the planarization layer 105 except at an emission area. For example, the bank 106 can have a bank hole through which the anode 151 corresponding to the emission area is exposed. The bank 106 can be made of, or include an inorganic insulating material, such as silicon nitride (SiNx) or silicon oxide (SiOx), or an organic insulating material, such as BCB, an acrylic resin or an imide-based resin, and embodiments of the present disclosure are not limited thereto.

The bank 106 can extend to the non-active area NA. For example, the bank 106 extends to the outside of the encapsulation part FSPM so as to fully cover the planarization layer 105 and suppress exposure of the planarization layer 105 to the outside. In other words, the bank 106 may extend beyond an edge of the encapsulation part FSPM so as to fully cover the planarization layer 105 and suppress exposure of the planarization layer 105 to the outside.

As such, the planarization layer 105 having a higher moisture absorption rate is covered by the bank 106 having a lower moisture absorption rate. Thus, when the display device 100 is exposed to moisture, it is possible to minimize moisture absorption and thus possible to improve reliability with respect to moisture permeation. Further, the first open hole OH1 formed in the planarization layer 105 is covered by the low potential power line contact portion 165 made of, or including a transparent conductive material. The transparent conductive material can include indium tin oxide (ITO), indium zinc oxide (IZO), indium gallium zinc oxide (IGZO) or the like, and embodiments of the present disclosure are not limited thereto. Thus, it is possible to suppress moisture permeation.

Herein, the bank 106 can be disposed to cover a part of an edge of the low potential power line contact portion 165 except a central portion of the low potential power line contact portion 165. Thus, a second hole OH2 can be formed to expose the central portion of the low potential power line contact portion 165. For example, the first open hole OH1 has a greater area than the second hole OH2, and the low potential power line contact portion 165 can have a greater area than the first open hole OH1.

The bank 106 can have a thickness of about 1 μm, but is not limited thereto.

The organic layer 152 can be disposed on the anode 151 exposed by the bank 106. The organic layer 152 can include an emission layer, an electron injection layer, an electron transport layer, a hole transport layer, a hole injection layer, and the like, and embodiments of the present disclosure are not limited thereto.

The organic layer 152 can extend to the non-active area NA.

The organic layer 152 can extend to a part of the non-active area NA so as to be spaced apart at a predetermined distance from the low potential power line 161. The predetermined distance may optionally depend on the display panel size.

In the non-active area NA, the organic layer 152 can be disposed on a part of the bank 106.

The cathode 153 can be disposed on the organic layer 152.

For the top emission type, the cathode 153 can contain a transparent conductive material. For example, the cathode 153 can be made of, or include indium tin oxide (ITO), indium zinc oxide (IZO), indium gallium zinc oxide (IGZO), or the like, and embodiments of the present disclosure are not limited thereto. For the bottom emission type, the cathode 153 can contain any one of the group consisting of metal materials such as gold (Au), silver (Ag), aluminum (Al), molybdenum (Mo), magnesium (Mg), palladium (Pd) and copper (Cu), or alloys thereof, and embodiments of the present disclosure are not limited thereto. Alternatively, the cathode 153 can have a laminated structure. The laminated structure can include a layer made of, or including a transparent conductive material such as indium tin oxide (ITO), indium zinc oxide (IZO) or indium gallium zinc oxide (IGZO). Further, the laminated structure can include a layer made of, or including a metal material such as gold (Au), silver (Ag), aluminum (Al), molybdenum (Mo), magnesium (Mg), palladium (Pd) and copper (Cu), or an alloy thereof. However, embodiments of the present disclosure are not limited thereto.

The cathode 153 can extend to the non-active area NA.

The cathode 153 can extend to the non-active area NA so as to be in contact with a part of the low potential power line contact portion 165 through the second hole OH2.

In the non-active area NA, the cathode 153 can be disposed to cover a side surface of the organic layer 152. In this example, the organic layer 152 can be disposed to be spaced apart at a predetermined distance from a tip end of the cathode 153. In other words, the organic layer 152 may be disposed to be spaced apart at a predetermined distance from a lateral end of the cathode 153, optionally contacting the conductive paste 260. However, embodiments of the present disclosure are not limited thereto. A tip end may be described as a lateral end.

The capping layer 107 made of, or including a material having high refractive index and light absorbance can be disposed on the organic light emitting diode 150 to reduce diffused reflection of external light.

The capping layer 107 can be an organic layer made of, or including an organic material, and can be omitted if necessary or desired.

The capping layer 107 can extend to the non-active area NA. In the non-active area NA, the capping layer 107 can be disposed on the cathode 153.

An encapsulation structure having a multilayer structure composed of, or including the sealing member 130 and the reinforcing substrate 140 can be disposed on the cathode 153. However, embodiments of the present disclosure are not limited thereto. The reinforcing substrate 140 can be omitted if necessary or desired. The sealing member 130 may be omitted if necessary.

A small-sized display panel used in mobile and portable devices has a small panel area. Thus, heat is rapidly dissipated from a device and there is little problem of adhesion. However, a large-sized panel used in monitors, tablets, and television sets has a large panel area. Thus, an encapsulation structure is required for optimal heat dissipation and adhesion.

Further, in order to compensate for the insufficient rigidity, the electroluminescent display device can further include a separate inner plate disposed on an encapsulation substrate. In this example, it is necessary to secure a space for receiving therein the separate inner plate. Due to the weight of the inner plate, there is a limit in slimming and weight reduction of the electroluminescent display device. Furthermore, a vertical separation space is generated due to an air gap generated between the encapsulation substrate and the inner plate by a thickness of an adhesive tape disposed to attach the encapsulation substrate and the inner plate to each other. Therefore, heat dissipation can be impacted or reduced. A vertical separation space may be in the stacking direction of the display panel.

Accordingly, in the first example embodiment of the present disclosure, the encapsulation structure having a multilayer structure including the sealing member 130 can be introduced. In the encapsulation structure, the separate inner plate can be removed and the reinforcing substrate 140 having a relatively larger thickness can be fixed. Thus, the encapsulation structure can suppress the occurrence of a process defect. A process defect may occur due to outside particles on the display (e.g., a contaminant or dust), or alignment issues when the display is manufactured, etc.

The sealing member 130 of the present disclosure can include a first adhesive layer 131 facing toward the substrate 101 and a second adhesive layer 133 facing toward the reinforcing substrate 140. Further, the sealing member 130 can include a barrier layer 132 disposed between the first adhesive layer 131 and the second adhesive layer 133.

Each of the first adhesive layer 131 and the second adhesive layer 133 can be made of, or include a polymer material having adhesiveness. For example, the first adhesive layer 131 can be made of, or include a polymer material of one of olefin-based, epoxy-based and acrylate-based polymers. Further, the second adhesive layer 133 can be made of, or include a polymer material of one of olefin-based, epoxy-based, acrylate-based, amine-based, phenol-based and acid anhydride-based polymers which do not contain a carboxyl group. For example, the second adhesive layer 133 can be made of, or include a polymer material which need not contain the carboxyl group for film uniformity and corrosion suppression of the barrier layer 132.

For heat dissipation of the substrate 101, at least the first adhesive layer 131 among the first and second adhesive layers 131 and 133 can be made of, or include a mixture including the polymer material having adhesiveness and metallic particles. For example, the metallic particles can be powder made of, or including Ni, but embodiments of the present disclosure are not limited thereto. The first adhesive layer 131 in direct contact with the substrate 101 is made of, or includes the mixture including the polymer material having adhesiveness and the metallic particles. Thus, the first adhesive layer 131 can have higher thermal conductivity than the polymer material having adhesiveness.

Likewise, the second adhesive layer 133 is made of, or includes a mixture including the polymer material having adhesiveness and the metallic particles. Thus, the second adhesive layer 133 can have higher thermal conductivity than the polymer material having adhesiveness.

In this way, a rate at which heat generated from the substrate 101 is dissipated through the sealing member 130 can be improved. Therefore, the heat dissipation from the substrate 101 can be improved.

Further, in order to suppress moisture permeation into the pixel unit 125, the first adhesive layer 131 can be made of, or include a mixture further including a hygroscopic inorganic filler. The hygroscopic inorganic filler can be at least one of barium oxide (BaO), calcium oxide (CaO), and magnesium oxide (MgO), but embodiments of the present disclosure are not limited thereto as other oxides, ceramics or inorganic materials can be use.

Unlike the first adhesive layer 131, the second adhesive layer 133 is not in direct contact with the pixel unit 125. Thus, there is no need for the second adhesive layer 133 to include the hygroscopic inorganic filler for suppressing moisture permeation into the pixel unit 125. Therefore, the second adhesive layer 133 need not include the hygroscopic inorganic filler, but can include only the polymer material having adhesiveness and the metallic particles. In this way, the amount of a relatively expensive hygroscopic inorganic filler injected into the sealing member 130 can be reduced. Therefore, the cost of preparing the sealing member 130 can be reduced.

Further, as the second adhesive layer 133 need not include the hygroscopic inorganic filler, a mixing ratio of the polymer material included in the second adhesive layer 133 can be increased, compared to that in the first adhesive layer 131. Thus, the adhesiveness of the second adhesive layer 133 can be higher than that of the first adhesive layer 131. Accordingly, as the reinforcing substrate 140 is more firmly fixed onto the second adhesive layer 133, the reliability of adhesion between the substrate 101 and the reinforcing substrate 140 can be further improved.

As the sealing member has a multilayer structure composed of, or including the first adhesive layer 131 and the second adhesive layer 133, the amount of warpage by which the display panel is bent can be reduced. Thus, the reliability can also be improved.

Each of the first and second adhesive layers 131 and 133 can have a thickness limited to be equal to or smaller than a threshold thickness at which a process defect can be suppressed. Further, the sum of the thicknesses of the first and second adhesive layers 131 and 133 can be limited to be equal to or greater than a threshold thickness at which the reliability in fixing the reinforcing substrate 140 can be secured, but embodiments of the present disclosure are not limited thereto.

For example, each of the first and second adhesive layers 131 and 133 can have a thickness in the range of 10 μm to 100 μm.

The barrier layer 132 can be made of, or include a metal material. For example, the barrier layer 132 can include a metal material such as Al, Cu, Sn, Ag, Fe, or Zn, but embodiments of the present disclosure are not limited thereto.

The barrier layer 132 can be introduced to implement a laminated structure for reinforcing the adhesion with the first and second adhesive layers 131 and 133 and reducing warpage.

For example, each of the first and second adhesive layers 131 and 133 includes a polymer material having adhesiveness. Accordingly, the barrier layer 132 made of, or including a relatively hard material (when compared with the first and second adhesive layers 131, 133) is disposed between the first adhesive layer 131 and the second adhesive layer 133. Thus, the first adhesive layer 131 and the second adhesive layer 133 are attached to one surface and the other surface of the barrier layer 132, respectively. Therefore, it is possible to improve adhesion, but embodiments of the present disclosure are not limited thereto.

In this example, the thickness of the barrier layer 132 can be limited to be smaller than the thicknesses of the first and second adhesive layers 131 and 133 to minimize an increase in thickness of the sealing member 130 caused by the barrier layer 132. For example, the thickness of the barrier layer 132 can be greater than 10 μm and smaller than each of the thicknesses of the first and second adhesive layers 131 and 133, but embodiments of the present disclosure are not limited thereto.

The sealing member 130 according to the first example embodiment of the present disclosure includes the first and second adhesive layers 131 and 133 separated via the barrier layer 132. Thus, the sealing member 130 can have a thickness of about twice that of a single-layer adhesive material while suppressing the occurrence of a process defect. Accordingly, the reinforcing substrate 140 fixed by the sealing member 130 can have a greater thickness. Therefore, the rigidity can be increased and the heat dissipation can be easily implemented. For example, when the sealing member 130 has a thickness in the range of 30 μm to 300 μm, the reinforcing substrate 140 can have a thickness in the range of 0.1 mm to 1.5 mm, but embodiments of the present disclosure are not limited thereto.

For example, the reinforcing substrate 140 can be made of, or include one material selected from glass and plastic polymers such as PET, but embodiments of the present disclosure are not limited thereto.

For example, the sealing member 130 and the reinforcing substrate 140 can extend to the non-active area NA so as to cover a part of the planarization layer 105 and a part of the bank 106.

For example, a tip end of the sealing member 130 and a tip end of the reinforcing substrate 140 can be located within, or overlap the second hole OH2. Thus, the first adhesive layer 131 can be in contact with the low potential power line contact portion 165 through the second hole OH2. The first adhesive layer 131 can be located only in a part of the second hole OH2, and the other part of the second hole OH2 can be exposed, but embodiments of the present disclosure are not limited thereto.

As described above, according to the present disclosure, the encapsulation structure has a multilayer part including the relatively thick reinforcing substrate 140. Thus, it is possible to achieve sufficient rigidity and heat dissipation. However, if a plastic polymer such as PET is used for the reinforcing substrate 140, it is difficult to suppress EMI. The encapsulation part FSPM of the present disclosure employs the reinforcing substrate 140 made of, or including a plastic polymer with the second adhesive layer 133, which is insulating, interposed therebetween. Therefore, electrical connection to the display part DP using a conductive tape on the encapsulation part FSPM as in the conventional method cannot be made.

Therefore, according to the present disclosure, the conductive paste 160 is applied to the side surface of the encapsulation part FSPM so as to be in contact with (or connected to) the side surface of the metallic barrier layer 132. Further, the conductive paste 160 is in contact with (or connected to) the low potential power line contact portion 165 through the second hole OH2 of which the other part is exposed. Thus, it is possible to improve EMI. For example, the barrier layer 132 can be connected to the low potential power line contact portion 165 through the conductive paste 160. Further, the low potential power line contact portion 165, the conductive paste 160, the barrier layer 132, and the cathode 153 can share the low potential power supply through the low potential power line 161.

For example, the conductive paste 160 can include a silver paste.

For example, the conductive paste 160 can have a width of at least 100 μm.

FIG. 6 illustrates an example where the conductive paste 160 extends to an upper surface of the reinforcing substrate 140 so as to cover a part of the upper surface of the reinforcing substrate 140. However, embodiments of the present disclosure are not limited thereto.

Referring to FIG. 6, one end of the conductive paste 160 is thinner than a main body of the conductive paste 160, and this thinner end is provided within the second hole OH2. When inside the second hole OH2, a thin portion of the first adhesive layer 131 can be pressed against the thinner end of the conductive paste 160 and contact the low potential power line contact portion 165, but such is not required, and the thinner end of the conductive paste 160 can directly contact the capping layer 107 and/or the cathode 153. Further, the thinner end of the conductive paste 160 need not directly contact the low potential power line contact portion 165, but a conductive material can be interposed between the thinner end of the conductive paste 160 and the low potential power line contact portion 165 to provide an electrical connection. In various embodiments of the present embodiment, the thinner end of the conductive paste 160 can also directly contact the low potential power line 161. In such an example, the conductive paste 160 can contact both the low potential power line contact portion 165 and the low potential power line 161, or the conductive paste 160 can directly contact the low potential power line 161, and indirectly (e.g., electrically) connected to the low potential power line contact portion 165 due to direct or electrical contact between the low potential power line contact portion 165 and the low potential power line 161.

Although the conductive paste 160 is shown as having a constant thickness in extending towards the reinforcing substrate 140, the embodiments of the present disclosure are not limited thereto. For example, a thickness of the conductive paste 160 can be greater at a top end, and decrease when approaching the second hole OH2, or the thickness of the conductive paste 160 can be greater near the second hole OH2, and decrease when approaching the reinforcing substrate 140. In other embodiments, a middle of the conductive paste 160 where the conductive paste 160 contacts the barrier layer 132 can have a greater thickness than those at the ends. In another example, the thickness of the conductive paste 160 that contacts the barrier layer 132 can be thinner than the ends.

In various embodiments of the present disclosure, the conductive paste 160 can be a layered structure or a laminate having the conductive past 160 provided on an inner side that contacts the barrier layer 132 and a resin or a tape that is on an outer side of the layered structure or the laminate. In this embodiment, the conductive paste 160 on the inner side can extend from the second hole OH2 to the barrier layer 132, while the resin or tape can extend from the second hole OH2 all the way to the top of the reinforcing substrate 140.

In various embodiments of the present disclosure, with reference to FIGS. 3-6, the conductive paste 160 provided between adjacent flexible films 180 need not be a single sheet or structure, but can be a plurality strips, or can be a structure having a unitary base at the second hole OH2, but has extending fingers that separate when approaching the barrier layer 132 or the top of the reinforcing substrate 140. For example, the structure can have an “E” shape. The reverse is also possible where the unitary base contacts the barrier layer 132, but the fingers extend when approaching the second hole OH2.

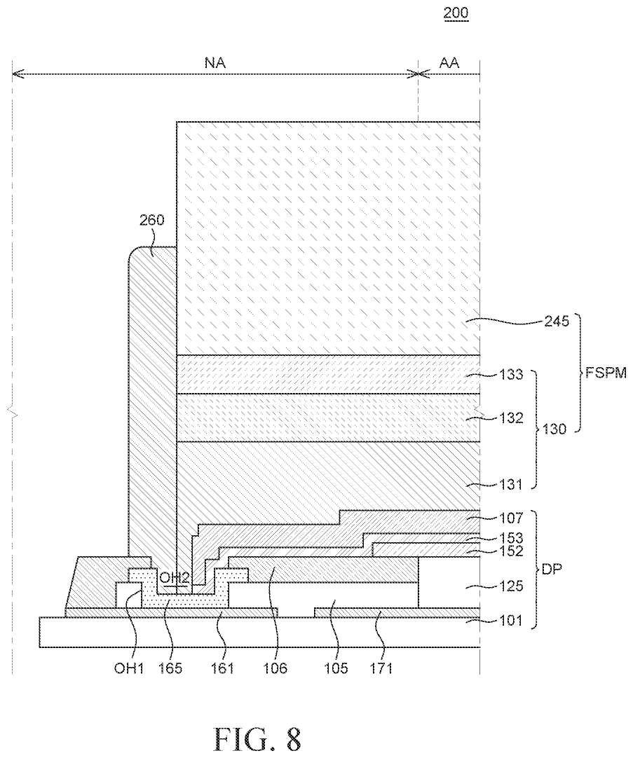

Meanwhile, a metal plate can substitute for the reinforcing substrate in the encapsulation part. This will be described in detail with reference to FIG. 8.

FIG. 8 is a cross-sectional view schematically illustrating an electroluminescent display device according to a second example embodiment of the present disclosure.

An electroluminescent display device 200 according to the second example embodiment of the present disclosure as shown in FIG. 8 is substantially the same as the electroluminescent display device 100 according to the first example embodiment of the present disclosure as shown in FIG. 6 except that the reinforcing substrate is substituted by a metal plate 245. Therefore, a repeated description of already described elements thereof will be omitted.

Referring to FIG. 8, the encapsulation part FSPM can be disposed on the display part DP in the electroluminescent display device 200 according to the second example embodiment in the same manner as in the above-described first example embodiment.

For example, the encapsulation part FSPM according to the second example embodiment of the present disclosure can be composed of, or include the sealing member 130 and the metal plate 245.

For example, the sealing member 130 can include the first adhesive layer 131 facing toward the substrate 101 and the second adhesive layer 133 facing toward the metal plate 245. Further, the sealing member 130 can include the barrier layer 132 disposed between the first adhesive layer 131 and the second adhesive layer 133.

Each of the first adhesive layer 131 and the second adhesive layer 133 can be made of, or include a polymer material having adhesiveness. For example, the first adhesive layer 131 can be made of, or include a polymer material of one of olefin-based, epoxy-based, and acrylate-based polymers, but embodiments of the present disclosure are not limited thereto. Further, the second adhesive layer 133 can be made of, or include a polymer material of one of olefin-based, epoxy-based, acrylate-based, amine-based, phenol-based and acid anhydride-based polymers which do not contain a carboxyl group. For example, the second adhesive layer 133 can be made of, or include a polymer material which need not contain the carboxyl group for film uniformity and corrosion suppression of the barrier layer 132, but embodiments of the present disclosure are not limited thereto.

For heat dissipation of the substrate 101, at least the first adhesive layer 131 among the first and second adhesive layers 131 and 133 can be made of, or include a mixture including the polymer material having adhesiveness and metallic particles. For example, the metallic particles can be powder made of, or including Ni. The first adhesive layer 131 in direct contact with the substrate 101 is made of, or includes the mixture including the polymer material having adhesiveness and the metallic particles. Thus, the first adhesive layer 131 can have higher thermal conductivity than the polymer material having adhesiveness.

Likewise, the second adhesive layer 133 is made of, or includes a mixture including the polymer material having adhesiveness and the metallic particles. Thus, the second adhesive layer 133 can have higher thermal conductivity than the polymer material having adhesiveness.

Further, in order to suppress moisture permeation into the pixel unit 125, the first adhesive layer 131 can be made of, or include a mixture further including a hygroscopic inorganic filler. The hygroscopic inorganic filler can be at least one of barium oxide (BaO), calcium oxide (CaO), and magnesium oxide (MgO), but embodiments of the present disclosure are not limited thereto.

Unlike the first adhesive layer 131, the second adhesive layer 133 is not in direct contact with the pixel unit 125. Thus, there is no need for the second adhesive layer 133 to include the hygroscopic inorganic filler for suppressing moisture permeation into the pixel unit 125. Therefore, the second adhesive layer 133 need not include the hygroscopic inorganic filler, but can include only the polymer material having adhesiveness and the metallic particles.

The barrier layer 132 can be made of, or include a metal material. For example, the barrier layer 132 can include a metal material such as Al, Cu, Sn, Ag, Fe, or Zn, but embodiments of the present disclosure are not limited thereto.

For example, the metal plate 245 can include a metal material such as Al, Cu, Sn, Ag, Fe, or Zn, but embodiments of the present disclosure are not limited thereto. Since the metal plate 245 made of, or including a metal material is added to the above-described first example embodiment, the heat dissipation can be further improved.

For example, the sealing member 130 and the metal plate 245 can extend to the non-active area NA so as to cover a part of the planarization layer 105 and a part of the bank 106, but embodiments of the present disclosure are not limited thereto.

For example, a tip end of the sealing member 130 and a tip end of the metal plate 245 can be located within, or overlap the second hole OH2. Thus, the first adhesive layer 131 can be in contact with the low potential power line contact portion 165 through the second hole OH2. Further, the first adhesive layer 131 can be located only in a part of the second hole OH2, and the other part can be exposed.

A conductive paste 260 can be applied to the side surface of the encapsulation part FSPM so as to be in contact with the side surface of the barrier layer 132. Further, the conductive paste 260 can be in contact with the low potential power line contact portion 165 through the second hole OH2 of which the other part is exposed.

For example, the barrier layer 132 can be connected to the low potential power line contact portion 165 through the conductive paste 260. Thus, the low potential power line contact portion 165, the conductive paste 260, the barrier layer 132, and the cathode 153 can share the low potential power supply through the low potential power line 161.

For example, the conductive paste 260 can include a silver paste.

For example, the conductive paste 260 can have a width of at least 100 μm.

FIG. 8 illustrates an example where the conductive paste 260 extends to a part of a side surface of the metal plate 245 and not to a top of the metal plate 245. However, the embodiments of the present disclosure are not limited thereto.

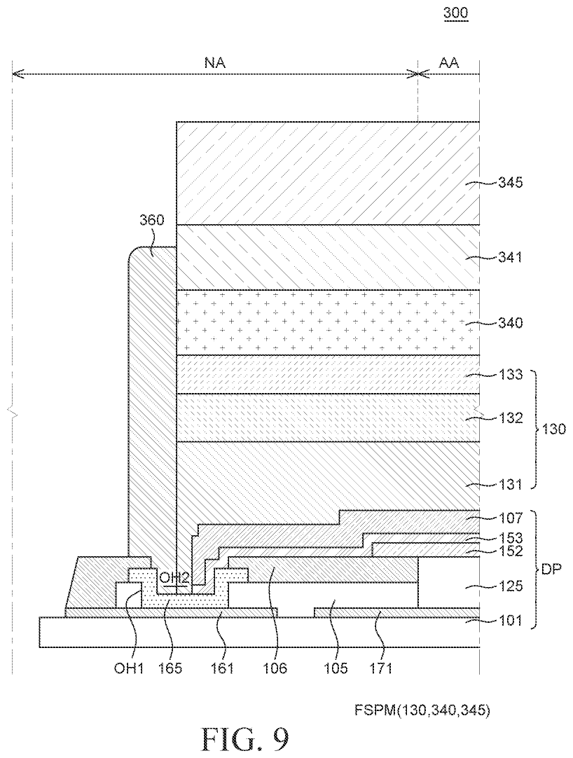

Meanwhile, a metal plate 245 can be further disposed on the reinforcing substrate with an adhesive layer interposed therebetween in the encapsulation part. This will be described in detail with reference to FIG. 9.

FIG. 9 is a cross-sectional view schematically illustrating an electroluminescent display device according to a third example embodiment of the present disclosure.

An electroluminescent display device 300 according to the third example embodiment of the present disclosure as shown in FIG. 9 is substantially the same as the electroluminescent display device 100 according to the first example embodiment of the present disclosure as shown in FIG. 6 except that a metal plate 345 is further disposed on a reinforcing substrate 340 with a third adhesive layer 341 interposed therebetween. Therefore, a repeated description of already described elements thereof will be omitted.

Referring to FIG. 9, the encapsulation part FSPM can be disposed on the display part DP in the electroluminescent display device 300 according to the third example embodiment in the same manner as in the above-described first and second example embodiments.

For example, the encapsulation part FSPM according to the third example embodiment of the present disclosure can be composed of, or include the sealing member 130, the reinforcing substrate 340, and the metal plate 345.

For example, the sealing member 130 can include the first adhesive layer 131 facing toward the substrate 101 and the second adhesive layer 133 facing toward the reinforcing substrate 340. Further, the sealing member 130 can include the barrier layer 132 disposed between the first adhesive layer 131 and the second adhesive layer 133.

For example, the reinforcing substrate 340 can be made of, or include one material selected from glass and plastic polymers such as PET, but embodiments of the present disclosure are not limited thereto.

The third adhesive layer 341 can be disposed on the reinforcing substrate 340, and the metal plate 345 can be disposed on the third adhesive layer 341. Thus, the encapsulation structure can have a greater thickness than that of the above-described first and second example embodiments. Therefore, the rigidity can be further increased. Further, since the metal plate 345 made of, or including a metal material is added, the heat dissipation can be further improved.

The third adhesive layer 341 can be made of, or include a polymer material having adhesiveness. For example, the third adhesive layer 341 can be made of, or include a polymer material of one of olefin-based, epoxy-based, acrylate-based, amine-based, phenol-based and acid anhydride-based polymers which do not contain a carboxyl group. However, embodiments of the present disclosure are not limited thereto.

The third adhesive layer 341 can be made of, or include a mixture including the polymer material having adhesiveness and metallic particles.

Further, the third adhesive layer 341 need not include a hygroscopic inorganic filler, but can include only the polymer material having adhesiveness and the metallic particles.

For example, the metal plate 345 can include a metal material such as Al, Cu, Sn, Ag, Fe, or Zn, but embodiments of the present disclosure are not limited thereto.

For example, the sealing member 130, the third adhesive layer 341, and the metal plate 345 can extend to the non-active area NA so as to cover a part of the planarization layer 105 and a part of the bank 106.

For example, a tip end of the sealing member 130, a tip end of the third adhesive layer 341, and a tip end of the metal plate 345 can be located within, or overlap the second hole OH2. Thus, the first adhesive layer 131 can be in contact with the low potential power line contact portion 165 through the second hole OH2. Further, as described above, the first adhesive layer 131 can be located only in a part of the second hole OH2, and the other part can be exposed.

A conductive paste 360 can be applied to the side surface of the encapsulation part FSPM so as to be in contact with the side surface of the barrier layer 132. Further, the conductive paste 360 can be in contact with the low potential power line contact portion 165 through the second hole OH2 of which the other part is exposed.

For example, the barrier layer 132 can be connected to the low potential power line contact portion 165 through the conductive paste 360. Thus, the low potential power line contact portion 165, the conductive paste 360, the barrier layer 132, and the cathode 153 can share the low potential power supply through the low potential power line 161.

For example, the conductive paste 360 can include a silver paste.

For example, the conductive paste 360 can have a width of at least 100 μm.

FIG. 9 illustrates an example where the conductive paste 360 extends to a part of a side surface of the third adhesive layer 341 and not to a top of the third adhesive layer or the top of the metal plate 345. However, embodiments of the present disclosure are not limited thereto.

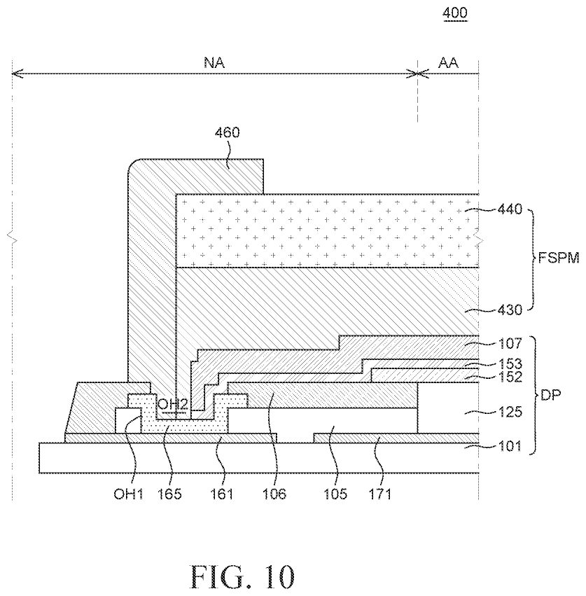

Meanwhile, the encapsulation structure of the present disclosure can be composed of, or include an adhesive layer and an encapsulation substrate. This will be described in detail with reference to FIG. 10.

FIG. 10 is a cross-sectional view schematically illustrating an electroluminescent display device according to a fourth example embodiment of the present disclosure.

An electroluminescent display device 400 according to the fourth example embodiment of the present disclosure as shown in FIG. 10 has some elements the same as the electroluminescent display device 100 according to the first example embodiment of the present disclosure as shown in FIG. 6 except that the encapsulation structure is composed of, or includes an adhesive layer 430 and an encapsulation substrate 440. Therefore, a repeated description of already described elements thereof will be omitted.

Referring to FIG. 10, the encapsulation part FSPM can be disposed on the display part DP in the electroluminescent display device 400 according to the fourth example embodiment in the same manner as in the above-described first, second and third example embodiments.

For example, the encapsulation part FSPM according to the fourth example embodiment of the present disclosure can be composed of, or include the adhesive layer 430 and the encapsulation substrate 440.

For example, the encapsulation substrate 440 can be formed as, or include a thin metal layer such as aluminum (Al) foil, but is not limited thereto.

The adhesive layer 430 can be made of, or include an optical clear adhesive (OCA) or a pressure sensitive adhesive (PAS).

For example, the adhesive layer 430 and the encapsulation substrate 440 can extend to the non-active area NA so as to cover a part of the planarization layer 105 and a part of the bank 106.

For example, a tip end of the adhesive layer 430 and a tip end of the encapsulation substrate 440 can be located within, or overlap the second hole OH2. Thus, the adhesive layer 430 can be in contact with the low potential power line contact portion 165 through the second hole OH2. Further, as described above, one part of the adhesive layer 430, such as the tip end, can be located only in a part of the second hole OH2, and the other part can be exposed.

For example, a conductive paste 460 can be disposed on the side surface of the encapsulation part FSPM so as to be in contact with a side surface of the encapsulation substrate 440. Further, the conductive paste 460 can be in contact with the low potential power line contact portion 165 through the second hole OH2 of which the other part is exposed.

For example, the encapsulation substrate 440 can be connected to the low potential power line contact portion 165 through the conductive paste 460. Thus, the low potential power line contact portion 165, the conductive paste 460, the encapsulation substrate 440, and the cathode 153 can share the low potential power supply through the low potential power line 161.

For example, the conductive paste 460 can include a silver paste.

For example, the conductive paste 460 can have a width of at least 100 μm.

FIG. 10 illustrates an example where the conductive paste 460 extends to an upper surface of the encapsulation substrate 440 so as to cover a part of the upper surface of the encapsulation substrate 440. However, embodiments of the present disclosure are not limited thereto.

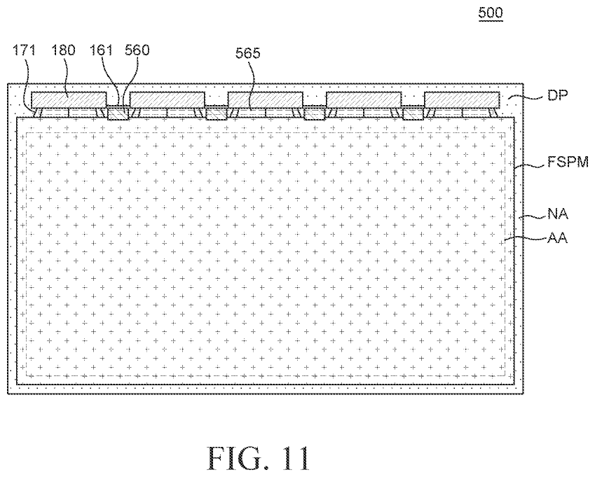

Meanwhile, as described above, the low potential power line contact portion 165 of the present disclosure can have a bar shape parallel to the width direction of the first short bar 172 between each of the flexible films. This will be described in detail with reference to FIG. 11.

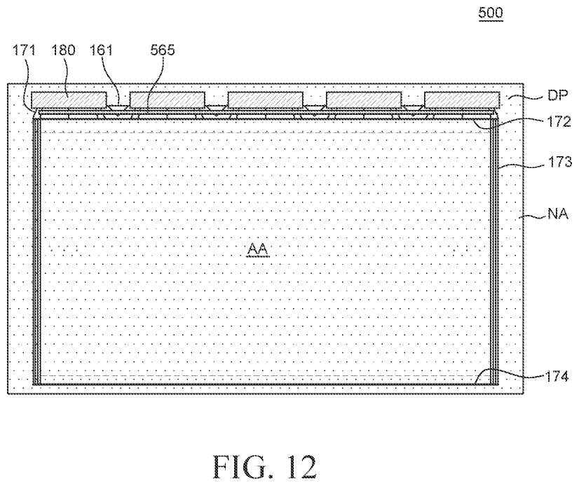

FIG. 11 and FIG. 12 are plan views schematically illustrating an electroluminescent display device according to a fifth example embodiment of the present disclosure.

An electroluminescent display device 500 according to the fifth example embodiment of the present disclosure as shown in FIG. 11 and FIG. 12 is substantially the same as the electroluminescent display device 100 according to the first example embodiment of the present disclosure as shown in FIG. 3 through FIG. 6 except the shape of a low potential power line contact portion 565. Therefore, a repeated description of already described elements thereof will be omitted.

FIG. 11 illustrates the planar structure of the electroluminescent display device 500 in which the encapsulation part FSPM is disposed on the display part DP. FIG. 12 illustrates the planar structure of the electroluminescent display device 500 in which the encapsulation part FSPM is removed.

Referring to FIG. 11 and FIG. 12, the electroluminescent display device 500 according to the fifth example embodiment of the present disclosure can include the display part DP, the encapsulation part FSPM, and the flexible film 180.

The encapsulation part FSPM can include the sealing member and the reinforcing substrate.

As described above, according to the present disclosure, a conductive paste 560 is applied to the side surface of the encapsulation part FSPM so as to be in contact with the side surface of the metallic barrier layer of the encapsulation part FSPM. Further, the low potential power line contact portion 565 connected to the low potential power line 161 is exposed between the flexible films 180 or source pads so as to be in contact with and electrically connected to the conductive paste 560. The exposed side surface of the barrier layer is connected to the low potential power line 161 by using the conductive paste 560. Here, the low potential power line 161 can share the low potential power supply with the data driver IC

For example, the flexible film 180 can be attached to the tip end on one side of the display part DP so as to cover the source pad and the driving IC. Further, a power voltage and a data voltage can be supplied to the plurality of sub-pixels and the circuits in the active area AA through a link line 171.

As described above, if the link line 171 is a high potential power line, it can be connected to the first short bar 172 disposed to be parallel to the width direction of the display part DP. Then, the link line 171 can be connected to the second short bar 174 through the plurality of high potential power lines 173 disposed in the active area AA. The high potential power line 173 can be disposed to be parallel to the height direction of the display part DP.

The first short bar 172 can be located at the upper end of the active area AA, and the second short bar 174 can be located at the lower end of the active area AA. However, embodiments of the present disclosure are not limited thereto.

The low potential power line 161 of the present disclosure can be disposed outside the link line 171 between the flexible films 180. In other words, the low potential power line 161 of the present disclosure may be disposed to extend beyond an edge of the link line 171 between the flexile films 180.

The low potential power line contact portion 565 is disposed on the low potential power line 161, and the low potential power line contact portion 565 can be in contact with (or connected to) the low potential power line 161.

For example, the low potential power line contact portion 565 can have a bar shape parallel to the width direction between the flexible film 180 and the first short bar 172. Alternatively, if high potential power lines are respectively disposed outside the outermost flexible films 180 on the left and right, the low potential power line contact portion 565 can be disposed not to overlap the high potential power lines. This is because, if the low potential power line contact portion 565 overlaps the high potential power lines, a short-circuit can occur. For example, the low potential power line contact portion 565 can have a ring shape excluding the left upper end and the right upper end of the display part DP where high potential power lines are respectively disposed. The low potential power line contact portion 565 having a ring shape can be in contact with an edge of the encapsulation part FSPM.

A part of an upper surface of the low potential power line contact portion 565 can be exposed as the planarization layer and/or the bank is removed. The cathode and the conductive paste 560 can be disposed on the exposed part of the upper surface of the low potential power line contact portion 565 so as to be in contact with (or connected to) the low potential power line contact portion 565.

The low potential power line contact portion 565 can have a bar shape parallel to the width direction of the first short bar 172 between each of the flexible films 180 as in the fifth example embodiment of the present disclosure. Alternatively, the low potential power line contact portion 565 can have a ring shape which is not disposed in the left upper end and the right upper end of the display part DP where high potential power lines are respectively disposed as in the fifth example embodiment of the present disclosure. In this example, the low potential power line contact portion 565 can be more effectively grounded.

The example embodiments of the present disclosure can also be described as follows:

According to an aspect of the present disclosure, there is provided an electroluminescent display device. The electroluminescent display device comprises a display part including an active area and a non-active area, an encapsulation part disposed over the display part, a flexible film attached to one side of the display part, a low potential power line supplied with low potential power from the flexible film and a conductive paste which is coated on a side surface of the encapsulation part between the flexible films and of which one side is connected to the low potential power line.

The encapsulation part can include a sealing member disposed over the display part and a reinforcing substrate disposed over the sealing member.

The sealing member can include a first adhesive layer, a second adhesive layer and a barrier layer disposed between the first adhesive layer and the second adhesive layer and made of a metal material.

The reinforcing substrate can be made of, or include one of glass or a plastic polymer.

The conductive paste can extend to an upper surface of the reinforcing substrate so as to cover a part of the upper surface of the reinforcing substrate.

The electroluminescent display device can further include a link line supplied with a power voltage or a data voltage from the flexible film, a first short bar connected to the link line and disposed in one direction of the display part, a plurality of high potential power lines connected to the first short bar and disposed in another direction in the active area and a second short bar connected to the high potential power lines and disposed in the one direction of the display part.

The low potential power line can be disposed between the link lines connected to the adjacent flexible films.

The electroluminescent display device can further include a low potential power line contact portion disposed over the low potential power line and connected to the low potential power line.

The electroluminescent display device can further include a planarization layer extending to the outside of the encapsulation part so as to cover a part of the low potential power line contact portion.

The planarization layer can include a first open hole prepared by removing a part of the planarization layer to expose a part of an upper surface of the low potential power line contact portion.

The electroluminescent display device can further include a bank extending to the outside of the encapsulation part so as to fully cover the planarization layer.

The bank can be disposed to cover a part of an edge of the low potential power line contact portion except a central portion of the low potential power line contact portion, and can include a second hole through which the central portion of the low potential power line contact portion is exposed.

The electroluminescent display device can further include a cathode extending to the non-active area and in contact with a part of the low potential power line contact portion through the second open hole.

A tip end of the encapsulation part can be located within the second open hole so as to be in contact with the low potential power line contact portion through the second hole, and the tip end of the encapsulation part can be located only in a part of the second open hole, and the other part of the second open hole can be exposed.

The conductive paste can be in contact with the low potential power line contact portion through the second hole of which the other part is exposed.

The conductive paste can include a silver paste. But other conductive materials can be used, such as copper or tin, among others.

The encapsulation part can include a sealing member disposed over the display part and a metal plate disposed over the sealing member and made of, or including a metal material.

The conductive paste can extend to a part of a side surface of the metal plate.

The electroluminescent display device can further include a metal plate disposed over the reinforcing substrate with an adhesive layer interposed therebetween.

The encapsulation part can include an adhesive layer disposed over the display part and an encapsulation substrate disposed over the adhesive layer.

The conductive paste can extend to an upper surface of the encapsulation substrate so as to cover a part of the upper surface of the encapsulation substrate.

The low potential power line contact portion can have an inverse triangular shape between the flexible films.

The low potential power line contact portion can have a bar shape parallel to one direction between the flexible film and the active area and need not overlap high potential power lines respectively disposed outside the outermost flexible films on the left and right.

The low potential power line contact portion can have a ring shape excluding a left upper end and a right upper end of the display part where high potential power lines are respectively disposed and can be in contact with an edge of the encapsulation part.

According to another aspect of the present disclosure, there is provided an electroluminescent display device. The electroluminescent display device a display part including an active area and a non-active area, an encapsulation part disposed on the display part, a plurality of flexible films disposed on one side of the display part; a low potential power line supplied with low potential power from at least one flexible film of the plurality of flexible films and a conductive paste disposed on a side surface of the encapsulation part between each flexible film of the plurality of flexible films and connected to the low potential power line.

The conductive paste can contact the side surface of the encapsulation part.

The electroluminescent display device can further include a planarization layer.

The planarization layer can include a first open hole to expose a part of an upper surface of the low potential power line contact portion.

The electroluminescent display device can further include a bank disposed on the substrate.

The bank can be disposed to cover a part of an edge of the low potential power line contact portion and can include a second hole through which the central portion of the low potential power line contact portion is exposed.

A tip end of the encapsulation part can be located within the second hole so as to be in contact with the low potential power line contact portion through the second hole.

The encapsulation part can include a sealing member and a reinforcing substrate disposed on the sealing member.

The reinforcing substrate can comprise a plastic polymer.

The reinforcing substrate can be a metal plate.

The encapsulation part can further include a metal plate disposed on the reinforcing substrate.

The encapsulation part can further include a third adhesive layer disposed between the reinforcing substrate and the metal plate.

The encapsulation part can further include an insulating adhesive layer disposed between the sealing member and the reinforcing substrate.

The sealing member can include a first adhesive layer and a second adhesive layer.

The sealing member can further include a barrier layer disposed between the first adhesive layer and the second adhesive layer.

The first adhesive layer can include a polymer material, and the second adhesive layer includes a polymer material.

The first adhesive layer can further include a hygroscopic inorganic filler.

The barrier layer can be connected to a low potential power line contact portion of the low potential power line through the conductive paste.

The conductive paste can extend to an upper surface of the reinforcing substrate so as to cover a part of the upper surface of the reinforcing substrate.

The electroluminescent display device can further include a high potential power line, wherein a low potential power line contact portion of the low potential power line does not overlap the high potential power line.

The electroluminescent display device can further include a cathode, the low potential power line contact portion, the conductive paste, the barrier layer, and the cathode can share the low potential power supply through the low potential power line.

The conductive paste can be connected to the low potential power line contact portion between each flexible film.

The sealing member can have a thickness of 30 μm to 300 μm and the reinforcing substrate can have a thickness of 0.1 mm to 1.5 mm.

It will be apparent to those skilled in the art that various modifications and variations can be made in the display apparatus of the present disclosure without departing from the technical idea or scope of the disclosures. Thus, it is intended that the present disclosure covers the modifications and variations of this disclosure provided they come within the scope of the appended claims and their equivalents.

What is claimed is:

1. An electroluminescent display device, comprising:
a display part including an active area and a non-active area;
an encapsulation part disposed over the display part;
one or more flexible films attached to one side of the display part;
a low potential power line supplied with low potential power from the one or more flexible films; and
a conductive element on a side surface of the encapsulation part adjacent the one or more flexible films and connected to the low potential power line.

2. The electroluminescent display device according to claim 1, wherein the encapsulation part includes:
a sealing member disposed over the display part; and
at least one of a reinforcing substrate disposed over the sealing member, and a metal plate disposed over the sealing member and including a first metal material.

3. The electroluminescent display device according to claim 2, wherein the sealing member includes:
a first adhesive layer;
a second adhesive layer; and
a barrier layer disposed between the first adhesive layer and the second adhesive layer and including a second metal material.

4. The electroluminescent display device according to claim 2, wherein the reinforcing substrate includes one of glass or a plastic polymer.

5. The electroluminescent display device according to claim 2, wherein the conductive element extends to an upper surface of the reinforcing substrate so as to cover a part of the upper surface of the reinforcing substrate, or
wherein the conductive element extends to a part of a side surface of the metal plate.

6. The electroluminescent display device according to claim 2, wherein the metal plate is disposed over the reinforcing substrate with an adhesive layer interposed therebetween.

7. The electroluminescent display device according to claim 1, further comprising:
a link line supplied with a power voltage or a data voltage from the one or more flexible films;
a first short bar connected to the link line and disposed in one direction of the display part;
a plurality of high potential power lines connected to the first short bar and disposed in another direction in the active area; and
a second short bar connected to the high potential power lines and disposed in the one direction of the display part.

8. The electroluminescent display device according to claim 7, wherein the low potential power line is disposed between the link lines connected to adjacent pair of the one or more flexible films.

9. The electroluminescent display device according to claim 1, further comprising:
a low potential power line contact portion disposed over the low potential power line and connected to the low potential power line,
wherein the low potential power line contact portion has one of:
an inverse triangular shape between adjacent pair of the one or more flexible films,
a bar shape parallel to one direction between the adjacent pair of the one or more flexible films and the active area and does not overlap high potential power lines respectively disposed outside of outermost flexible films of the one or more flexible films on the left and right, or
a ring shape excluding a left upper end and a right upper end of the display part where high potential power lines are respectively disposed and is in contact with an edge of the encapsulation part.

10. The electroluminescent display device according to claim 9, further comprising:
a planarization layer extending to the outside of the encapsulation part so as to cover a part of the low potential power line contact portion.

11. The electroluminescent display device according to claim 10, wherein the planarization layer includes a first open hole prepared by removing a part of the planarization layer to expose a part of an upper surface of the low potential power line contact portion.

12. The electroluminescent display device according to claim 11, further comprising:
a bank extending to an outside of the encapsulation part so as to fully cover the planarization layer.

13. The electroluminescent display device according to claim 12, wherein the bank is disposed to cover a part of an edge of the low potential power line contact portion except a central portion of the low potential power line contact portion, and includes a second hole through which the central portion of the low potential power line contact portion is exposed.

14. The electroluminescent display device according to claim 13, further comprising:
a cathode extending to the non-active area and in contact with a part of the low potential power line contact portion through the second open hole.

15. The electroluminescent display device according to claim 13, wherein a tip end of the encapsulation part is located within the second open hole so as to be in contact with the low potential power line contact portion through the second hole, and
wherein the tip end of the encapsulation part is located only in a part of the second open hole, and another part of the second open hole is exposed.

16. The electroluminescent display device according to claim 15, wherein the conductive element is in contact with the low potential power line contact portion through the second hole of which the another part is exposed.

17. The electroluminescent display device according to claim 1, wherein the conductive element includes a silver paste.

18. The electroluminescent display device according to claim 1, wherein the encapsulation part includes:
an adhesive layer disposed over the display part; and
an encapsulation substrate disposed over the adhesive layer.

19. The electroluminescent display device according to claim 18, wherein the conductive element extends to an upper surface of the encapsulation substrate so as to cover a part of the upper surface of the encapsulation substrate.

20. A display device, comprising:
a display part;
an encapsulation part disposed on the display part;
flexible films on a periphery of the display part;
a power line extending between an adjacent pair of the flexible films, and having an exposed portion defined by at least one hole; and
a conductive element extending from the encapsulation part towards the power line on an outer periphery of the encapsulation part, and electrically connecting the power line to the encapsulation part at the at least one hole But other conductive materials can be used, such as copper or tin, among others.
